(19) United States
(12) Patent Application Publication
(10) Pub. No.: US 2024/0042481 A1
(43) Pub. Date: Feb. 8, 2024

(54) Methods and Apparatuses for Fabricating Polymeric Conformal Coatings, Parts Coated With Polymeric Conformal Coatings, and Optical Apparatus Including Said Parts

(71) Applicant: UCL BUSINESS LTD, London (GB)

(72) Inventors: Paul Beard, London (GB); Edward Zhang, London (GB)

(21) Appl. No.: 17/641,786

(22) PCT Filed: Sep. 7, 2020
(86) PCT No.: PCT/GB2020/052146

§ 371 Date: Mar. 9, 2022

(30) Foreign Application Priority Data
Sep. 12, 2019 (GB) 1913141.6

(51) Int. Cl. B05D 1/00; G01B 9/02017; G01B 9/02; G01B 9/02015

(52) U.S. Cl. CPC B05D 1/60; G01B 9/02017; G01B 9/02049; G01B 9/02031; G01B 9/02034; C23C 16/4488

(57) ABSTRACT

A method of forming a Chemically Vapour Deposited polymeric conformal coating on a surface of a part (23). The method comprises placing the part (23) and a deposition regulator (28) in a deposition chamber (22); dispersing a gas into the chamber (22) from which the polymeric coating is deposited on the surface. The deposition regulator (28) is configured to control a localised flow of the gas in the deposition chamber (22) to promote a more uniform layer thickness of the polymeric coating on the surface.

### TECHNICAL FIELD

The present disclosure relates generally to methods and apparatuses for fabricating polymeric conformal coatings, and parts coated with polymeric conformal coatings. The present disclosure also relates to forming coated parts for use as Fabry Perot interferometers for use, for example, in an optical ultrasound readout system.

### BACKGROUND

Methods of coating parts with polymeric conformal coatings, such as Parylene, have been in widespread use primarily for encapsulation of the parts for their protection and to act as a barrier from the environment, often for medical and electronics applications.

Polymeric conformal coatings can be formed, for example, by the condensation of a monomer gas onto a surface of a part to be coated, typically at ambient temperatures and low pressures (near vacuum of around 10-20 Pa), in a deposition chamber. On condensation, the monomer simultaneously adsorbs into the surface and polymerises into long polymer chains to grow a conformal polymer coating layer on the surface. The monomer gas is typically created by providing a vaporised dimer precursor into a pyrolysis chamber where it is heated at pressure to create the monomer gas which is then dispersed into the evacuated deposition chamber, whereupon the polymer coating of all surfaces within the chamber commences. The polymer coating typically progresses at uniform growth rates and so the growth of the coating can be selectably controlled to a desired thickness.

An example of a use of a Parylene coating is in the provision of an interferometric cavity of a Fabry Perot interferometer. Here, by forming a Parylene coating on an optically reflective surface of a substrate, and by forming a further optically reflective surface on the facing surface of the deposited Parylene layer, a Fabry Perot interferometer or etalon can be formed with the Parylene layer providing the interferometeric cavity between two reflective surfaces.

A polymer film interferometer such as this has a use in developing apparatus to deliver optical ultrasound sensing and imaging for medical imaging, non-destructive testing, and other applications. The fabricated Fabry Perot cavities can be used to sense other measurands, such as temperature, quasi-static pressure, etc.

In one optical ultrasound approach, a polymer film interferometer provides an optical component that exhibits narrowband reflection of incident light in the cavity by a reflected power responsive to whether the phase of multiple light reflections in the cavity is such that the reflected light beams interfere constructively or destructively. This is represented by φ, the phase difference between the optical fields reflected from the two mirrors of the Fabry Perot Interferometer. The variation of the optical power of the reflected light with the value of φ gives an Interferometer Transfer Function (ITF) as shown in FIG. 4A. By placing an acoustically sensitive surface of the polymer film interferometer in contact with a medium having an acoustic (ultrasound) field, the compression and deflection of the polymer film cavity modulates the phase difference of the light in the cavity by an amount dφ and in doing so modulates the power of the reflected interrogation signal by an amount dPᵣ. In this way, the interferometer has a transfer function responsive to an acoustic field applied to it and so it can be used as a sensor to transduce the acoustic field signal.

Thus for optical ultrasound imaging, the localised ITF modulation caused by an incident acoustic field can be interrogated by illuminating the etalon with a laser and monitoring the variation of the reflected optical power at locations across the surface of the etalon. The acoustic field can thus be recovered from the modulated interrogation light signal, allowing, where it is sensed at multiple points, an image of the target tissue to be constructed, for example, using tomographic techniques.

As the reflected optical power Pᵣ, and the magnitude of the variation of the reflected optical power due to an incident acoustic field dPᵣ, vary with the phase difference φ of the reflected optical fields in the interferometer cavity, the sensitivity of the interferometer to an incident acoustic can vary significantly across with polymer film interferometer with even sub-micron variations in cavity thickness across the surface.

Thus microscale variations in the deposited polymer coating thickness lead to a complicated optical ultrasound control interrogation system being needed that can determine and control for variations in sensitivity across the interferometric sensor.

As a result, despite the potential of medical imaging using optical ultrasound detection, high quality, high resolution, fast-acquired, imaging results have been difficult to achieve with polymer film interferometers. Further, the time taken to reveal an image of a target typically takes a significant amount of time to capture and then process due to the complicated control and readout techniques being needed. This makes current ultrasound optical imaging techniques, for use, for example, in photoacoustic tomography, impractical for clinical research and practice, and also for applications in life sciences research.

In addition to Fabry Perot etalons, there are other contexts in which layer thickness is highly important, and which call for well controlled layer thickness. It is in this context that the presently disclosed subject matter has been devised.

### BRIEF SUMMARY OF THE DISCLOSURE

According to a first aspect, a method of forming a vapour deposited polymeric conformal coating on a surface of a part is provided, comprising: placing the part and a deposition regulator in a deposition chamber; dispersing a gas into the chamber from which the polymeric coating is deposited on the surface; wherein the deposition regulator is configured to control a localised flow of the gas in the deposition chamber to promote a more uniform layer thickness of the polymeric coating on the surface. In some embodiments, the method may comprise forming a polymeric conformal coating by chemical vapour deposition (CVD). In a CVD process, the gas may comprise monomer particles that condense an polymerise to form the polymeric coating on the surface. In other embodiments, the method may comprise forming a polymeric conformal coating by physical vapour deposition. For example a polymer may be dissolved in a solvent and the solvent frozen. Material ablated from the frozen solvent (e.g. with a laser) may be evaporated to disperse polymer vapour particles in the chamber, which will form a polymeric layer on the substrate.

In the deposition chamber, the gas freely disperses to condense and adsorb (and optionally, to polymerise) on surfaces with which they interact. While the coating growth rate is nominally uniform, normally, where the application of the polymeric coating to the part is not required to have any particular form on microscale dimensions, other than to conform to a surface, for example for encapsulation, uncontrolled variations in the coating growth rate do arise. These uncontrolled variations resulting from the flow of the monomer gas throughout the chamber, the chamber geometry, the rotation of the part if on any turntable or tumbler, the geometry of any stage, rack or mounting surface acting as a support for the part and its interaction with the chamber geometry, developing diffusion of the gas pursuant to deposition, and thermal effects. For the majority of applications, these uncontrolled variations in the coating thickness are of no consequence.

However, in some applications, uncontrolled variations in the coating thickness can cause a significant impairment to the usefulness of the part, or the operation and effectiveness of the system incorporating the part. This is the case, for example, with a polymer film interferometer in which uncontrolled microscale variations in the thickness of the Parylene coating create significant complications with easy, efficient and accurate readout.

The present inventors have realised that the polymer deposition process can be controlled to provide a polymeric coating layer with a more uniform layer thickness by placing in the deposition chamber a deposition regulator, which may comprise one or more components. The arrangement and configuration of the deposition regulator may control the flow of the monomer gas particles around the part during deposition and ongoing dispersion, thereby promoting more uniform deposition of the polymeric coating on the surface.

Suitable deposition regulation components may include at least one of: baffles, opposing plates, regulation rings, meshes, flow control screens. In some embodiments a coating layer can be controlled to achieve a substantially uniform thickness (e.g. of less than 1%) over length scale of at least 10 mm, at least 5 mm or at least 1 mm.

In some embodiments, the surface to be coated is a first reflective surface of a part that is, when finished, to provide a Fabry Perot interferometer, wherein the polymeric coating is to provide an optical cavity of the Fabry Perot interferometer.

In some embodiments, the method further comprises depositing one or more layers on the surface of the deposited polymeric coating to provide a second reflective surface in opposition to the first reflective surface, to thereby form the Fabry Perot interferometer.

In some embodiments, the arrangement of the deposition regulator is configured to achieve a thickness variation of the deposited coating across the coating surface of less than 5%, optionally less than 2%, optionally less than 1%. In embodiments, the thickness variation of the deposited coating across the surface is achieved over a length scale of at least 10 mm, optionally at least 20 mm, optionally at least 30 mm, optionally at least 50 mm along one dimension of the surface. In embodiments, The thickness variation of less than 5%, optionally less than 2%, optionally less than 1% may be achieved over a length scale on the surface of at least 1 mm, optionally at least 5 mm, optionally at least 10 mm, optionally at least 20 mm, optionally at least 30 mm, optionally at least 50 mm along one dimension of the surface.

In some embodiments, the deposition regulator components comprises one or more of:
A parallel plate in opposition and substantially parallel to the surface to be coated, for instance parallel to a surface of a support on which the parts to be coated are placed;
An annular ring plate in opposition and substantially parallel to the surface to be coated, for instance parallel to a supporting surface of a support on which the parts to be coated are placed, the annular ring plate having a central opening;
A mesh grid in opposition and substantially parallel to the surface to be coated, for instance parallel to a supporting surface of the support on which the parts to be coated are placed;
An annular ring baffle arranged around and substantially perpendicular to the surface to be coated, for instance, perpendicular to a supporting surface of the support on which the parts to be coated are placed.

In some embodiments, a supporting surface of the support, or the part or parts to be coated, or the surface for coating thereof, has substantially the same diameter as any parallel plate, annular ring, mesh grid and annular ring baffle.

In some embodiments, one or more of a parallel plate, annular ring plate, and mesh grid are spaced at least 4 mm, optionally at least 5 mm, optionally at least 7 mm, optionally at least 10 mm, optionally at least 15 mm, from the supporting surface of the support, or from the part or parts to be coated, or from the surface for coating.

In some embodiments, the annular ring baffle extends at least 4 mm, optionally at least 5 mm, optionally at least 7 mm, optionally at least 10 mm, optionally at least 15 mm from the supporting surface of the support on which the parts to be coated are placed, or from the part to be coated, or from the surface for coating.

In accordance with these embodiments, arranging the deposition regulator in this way promotes the deposition of a highly uniform thickness layer, for example on a planar substrate to provide a polymer film interferometer.

In some embodiments, the polymeric coating is sandwiched between two reflective surfaces.

Generally, methods in accordance with embodiments can achieve variations in the thickness of the coating down to tenths or hundredths of a micron on a polymer conformal coating having a thickness on the order of microns to tens or even hundreds of microns.

In some embodiments, the method further comprises evacuating the deposition chamber such that the internal pressure of the chamber is less than 20 Pa.

In some embodiments, the deposition chamber is substantially at the ambient temperature.

In some embodiments, the support is or is placed on a turntable in the deposition chamber.

Viewed from another aspect, the present disclosure provides apparatus for forming a vapour deposited polymeric conformal coating on a surface of a part to provide a polymeric coating layer. The apparatus comprises: a deposition chamber for receiving the part; and a deposition regulator in the deposition chamber; one or more chamber inlets configured to disperse a gas into the chamber from which the polymeric coating is deposited on the surface; and wherein the deposition regulator is configured to control a localised flow of the gas in the deposition chamber to promote a more uniform layer thickness of the polymeric coating on the surface.

Viewed from another aspect, the present disclosure provides a coated part having a polymeric conformal coating layer formed by a process in accordance with aspects of the present disclosure.

In some embodiments, the polymeric coating layer has a substantially uniform thickness over the coated surface.

In some embodiments, the polymeric coating layer has a thickness variation of less than 5%, optionally less than 2%, optionally less than 1%. In embodiments, the thickness variation of the polymeric coating is over a length scale of at least 1 mm, optionally at least 5 mm, optionally at least 10 mm, optionally at least optionally at least 30 mm, optionally at least 50 mm along the coating surface (e.g. in one dimension).

In some embodiments, the coated part is a Fabry-Perot interferometer, and wherein the polymeric coating provides the interferometric cavity of the Fabry-Perot interferometer.

Viewed from another aspect, the present disclosure provides apparatus for performing acoustic sensing. The apparatus comprises: a sensor head having a Fabry Perot interferometer comprising a coated part according to an aspect of the invention, the coated part providing an acoustically sensitive surface arranged as a reflective surface of the Fabry Perot interferometer cavity, and the polymeric coating layer forming the cavity of the Fabry Perot interferometer, wherein an acoustic field incident upon the acoustically sensitive surface modulates the optical path length in the cavity. Reflective surfaces may be formed on the coated part on either side of the polymeric conformal coating layer to form the Fabry Perot interferometer.

In some embodiments, the polymeric coating layer on a coated surface of the part has a substantially uniform thickness over the surface. In embodiments, the polymeric coating layer on the surface has a thickness variation of less than 5%, optionally less than 2%, optionally less than 1%. In embodiments, the surface is at least 20 mm, optionally at least 30 mm, optionally at least 50 mm along one dimension of the surface. The thickness variation of less than 5%, optionally less than 2%, optionally less than 1% may be achieved over the surface over at least 20 mm, optionally at least optionally at least 50 mm along one dimension of the surface.

In this way, an optical ultrasound imaging apparatus can be provided with a relatively straightforward, effective and fast readout as the interferometer has less sensitivity variation across its surface, meaning that less control is required to adjust the readout apparatus to accurately control for these sensitivity variations.

The apparatus may further comprise a light source, optionally wavelength tuneable, for generating one or more interrogation beams of electromagnetic radiation. The apparatus may further comprise controllable beam directing means operable to direct the one or more interrogation beams onto addressable locations (x,y) across said acoustically sensitive surface. The apparatus may further comprise: phase control means for controlling the phase difference between the optical fields reflected from the two mirrors of the Fabry Perot Interferometer, such as by tuning the wavelength of light or by controlling the cavity thickness, to thereby adjust the sensitivity of the apparatus. The apparatus may further comprise detection means configured to receive and determine one or more values representative of the power of the reflected one or more interrogation beams from the addressable locations (x,y). The apparatus may further comprise a controller configured to, in use, operate one or more of the light source, beam directing means, phase control means, and detection means to: interrogate addressable locations (x,y) of the sensor head at a phase difference of the reflected light fields in the cavity at which the reflected light is sensitive to the incident acoustic field; and receive, from detection means, values representative of the power of the reflected interrogation beam for each interrogated addressable location of the region; and form an image indicative of the signal modulated on the reflected one or more interrogation beams by the acoustic field incident on the acoustically sensitive surface at addressable locations (x,y) across the sensitive surface.

### BRIEF DESCRIPTION OF THE DRAWINGS

Certain preferred embodiments of aspects of the disclosure will now be described, by way of example only, and with reference to the accompanying drawings, in which:

FIG. 1 is a perspective view of a planar Fabry Perot etalon provided in a sensor head in accordance with embodiments of the disclosure;

FIG. 2 is a schematic illustration of an apparatus for performing an optical ultrasound imaging in accordance with embodiments of aspects of the disclosure;

FIG. 3 is a sectional view of a planar Fabry Perot etalon in accordance with embodiments of the disclosure;

FIG. 4A is an illustrative graph of an ITF in phase space showing the relationship between reflected interrogation beam power and the phase difference of an interrogation beam for a Fabry Perot sensor in accordance with embodiments of the disclosure, including an indication of a selection of a bias point;

FIG. 4B is a plot of an ITF in wavelength space showing the relationship between reflected interrogation beam power and the wavelength of an interrogation beam for a Fabry Perot sensor in accordance with embodiments of the disclosure, including an indication of a selection of a bias wavelength;

FIG. 5 shows an apparatus for forming a Chemically Vapour Deposited polymeric conformal coating on one or more coating surfaces of a part to be coated for use in embodiments of aspects of the disclosure.

FIG. 6A shows an exploded view of deposition regulation components for use in achieving a polymer coating of substantially uniform thickness on microscale dimensions in accordance with embodiments of aspects of the present disclosure;

FIG. 6B shows an arrangement of the deposition regulation components shown in FIG. 6A in juxtaposition with a part to be coated configured to promote the polymeric coating to be deposited to have substantially uniform thickness on microscale dimensions;

FIG. 7 is a graph showing the measured percentage variation in coating thickness across different surfaces coated using different example arrangements of deposition regulation components; and

FIG. 8 illustrates coating of relatively small parts, in which the surface to be coated is planarised by aligning the surfaces of the smaller parts with a larger surface, or in which the smaller parts are cut from a larger part.

### DESCRIPTION OF THE EMBODIMENTS

An apparatus and method for forming a Chemically Vapour Deposited polymeric conformal coating on a surface (or surfaces) of a part will now be described with reference to FIG. 5. The apparatus and method can be used to form polymeric conformal coatings having highly uniform layer thickness for use as a polymer film interferometers, or other structure. While the following description relates to coating with a Parylene, it is to be understood that this is not limiting, and any monomer that condenses and forms polymer chains to grow a conformal layer may be used in embodiments.

The apparatus has an inlet chamber 18, a pyrolysis chamber 20 and a deposition chamber 22 connected by hermetically sealed tubing 24. The pyrolysis chamber 20 is connected to the chamber 22 by a pipe 25, which terminates in the chamber with one or more nozzles, from which monomer particles are dispersed into the chamber 22. A part 23 to be coated, which may be a backing stub for a Fabry Perot interferometer having a thin film dichroic mirror already deposited thereon, or a cleaved optical fibre, or any other part for coating, is introduced to the deposition chamber 22. The part 23 may be supported on a support 26 of the deposition chamber, which may include or itself be supported by a turntable or tumbler mechanism to rotate the part 23 during coating and encourage circulation of and within the monomer gas. The dispersion or flow of monomers from the one or more nozzles may be substantially transverse to the surface to be coated. The rotation of the part 23 in combination with the transverse flow of monomers may assist in achieving more uniform layer thickness, in combination with the deposition regulator. As will be described further below, to enable scaling and mass production of coated parts, the support 26 may include a tower or other multi-layered or multi-surfaced structure on which multiple parts can be placed, or temporarily adhered (for example, if upside down) such that they can all be coated.

Areas of the part 23 that are to remain free of coating may be covered, for example with a simple adhesive covering tape, since the active parylene monomer will polymerise on any available surface. The surface covering tape will mask covered regions of a surface of the part to prevent deposition. Such a surface covering will be in contact with the surface, and will tend to be very thin, and will consequently not control a localised flow of the dispersed monomer particles in the deposition chamber to promote a more uniform layer thickness at regions of the surface that are to be coated. It is important that the part 23 is clean and surface contaminants such as oils and ions are removed prior to the coating process. Conventional solvents may be used to perform the cleaning process. Prior to the coating process, a multi-molecular layer of an organo-silane may also be applied to pretreat the parts of the optical fibre that are to be coated. This functions as an adhesion promoter, allowing the polymers to be applied to virtually any vacuum stable material.

In use, in a first step, a precursor of the polymer coating, in this case a dimer parylene, is introduced into inlet chamber 18 via tubing where in embodiments it is vaporised at approximately 150 C and in a 100 Pa vacuum.

In a second step, the vaporised dimer continues via tubing 24 to the pyrolysis chamber 20 where in embodiments it is heated to a temperature of approximately 680 C in a 50 Pa vacuum. This forms a monomer gas for deposition onto the part 23.

In a third step, the highly active monomer gas, in this embodiment of parylene, continues via tubing 25 to the deposition chamber 22. The deposition chamber is typically at ambient room temperature and at a weak vacuum pressure, for example having an internal pressure of around 10 Pa. The part 23 is placed in the deposition chamber 22 with an exposed surface onto which the parylene monomer can polymerise.

The monomer simultaneously condenses, adsorbs and polymerises on all available surfaces of the part 23 to produce a high molecular-weight polymer coating. In particular, the polymer deposition process does not entrap air since the process is carried out in an effective vacuum. The part 23 is then removed and the coating thickness can be checked.

Due to the chemical properties of the coating material and the polymerisation mechanism, the coating formed is conformal and the coating growth rate is nominally uniform throughout the chamber. However, it has been found that coating growth rate can vary significantly, subject to localised flow of dispersed monomer particles and other factors.

For example, there are three common forms of the parylene polymer, parylene C, parylene N and parylene D. The polymers each have high hydrophobicity and as such are particularly useful as sensors for medical probe applications. Typically, the parylene coating grows at a nominal rate of approximately 0.21 μm per minute for parylene C and a slower rate for parylene N.

To achieve fine control over the deposition and polymer growth process to form a polymer coating with more uniform layer thickness, a deposition regulator 28 is also placed in the deposition chamber 22, spaced apart from the surface (of the part 23) to be coated. The deposition regulator is configured to promote more uniform growth rates, and consequently more uniform layer thickness of the polymeric coating. The highly uniform layer thickness may make the polymer coating more suitable for an intended use of the part (e.g. producing an etalon with more consistent sensitivity to a particular wavelength over different regions of the surface thereof).

The deposition regulator may comprise a suitable configuration and arrangement of components, such as baffles, opposing plates, regulation rings, meshes, flow control screens, etc, designed appropriately to control the bulk or localised flow of gas monomers and thereby improve thickness uniformity of the deposited conformal polymer layer. For example, a coating layer can be controlled to achieve a substantially uniform thickness (of less than 1%) over a dimension suitable for use as polymer film interferometer for optical ultrasound applications (e.g. 1 mm, 2 mm, 5 mm, or more).

The particular configuration and arrangement of the deposition regulator components needed to form a coating layer on a particular part with more uniform thickness can be informed by empirical methods such as by iterative trial and error, or by semi-empirical or theoretical methods such as by appropriate modelling for example of localised flow of dispersed gas around a model of the deposition regulator components in relation to the part, using suitable software. As such, the devising of the configuration and arrangement of the deposition regulator to achieve a desired structure may be performed based on the teaching of the present disclosure.

A number of non-limiting examples will now be described with reference to the drawings.

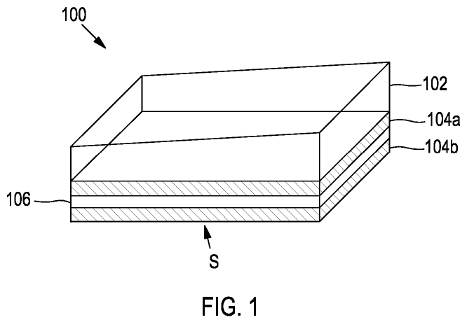

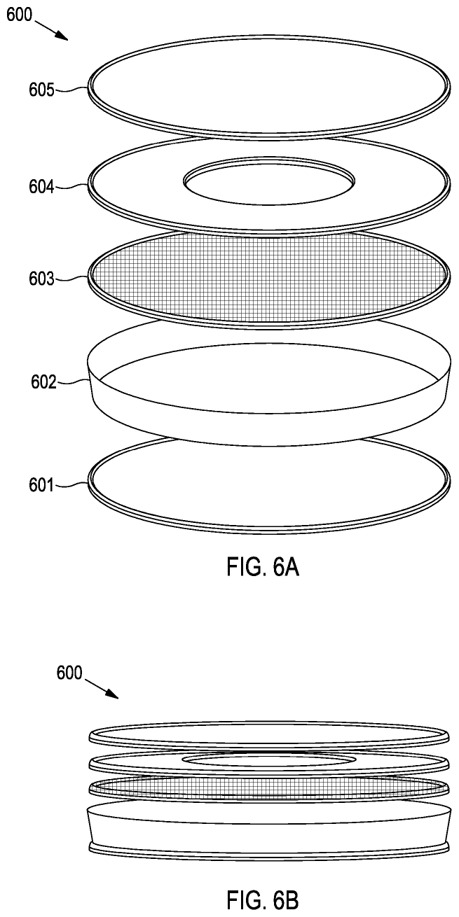

FIG. 6A shows an exploded view of an arrangement of components of a deposition regulator 600 configured for use in achieving a polymer coating of substantially uniform thickness in accordance with an embodiment of aspects of the present disclosure. This may be used to form, for example, an interferometric cavity layer of a very high quality polymeric film interferometer, such as that shown in FIG. 1, and described further below.

The deposition regulator 600, is shown assembled in FIG. 6B. A a support 601 is provided, upon which parts to be coated may be placed in use. To achieve a uniform coating, the parts to be coated may be arranged at the same height and as close together as possible to avoid disturbing the flow, the aim being to create a flat surface. In embodiments, the part or parts to be coated may themselves be arranged as the support or may support the deposition regulator 600. For example, the part to be coated may be a larger, sheet-like structure that may be coated. The part may be cut into smaller sections after coating for use.

In embodiments, an annular ring baffle 602, having an annular wall, may be arranged around and extending substantially perpendicular to the supporting surface of the support 601 on which the parts to be coated are placed. The annular ring baffle 602 may provide flow control by serving to inhibit immediate circulation of dispersed monomer gas particles to parts arranged towards the edge of the surface of the support 601. The annular ring baffle 602 tends to reduce the propensity for a transverse flow of monomer particles over the surface to result in a thicker layer in the portions of the surface that are closest to the inlet into the chamber (or which are brought by rotation into closest proximity with the inlet).

In embodiments, a mesh grid 603 may be arranged spaced apart in opposition and substantially parallel to a supporting surface of the support 601 on which the parts to be coated are placed. When separated from the parts to be coated at a distance, the mesh grid 603 may provide flow control by encouraging the even dispersion of the circulating monomer gas particles across and towards the surface of the support 601, thereby promoting a uniform growth rate across the surface.

In embodiments, an annular ring plate 604 may be arranged spaced apart in opposition and substantially parallel to a supporting surface of the support 601 on which the parts to be coated are placed. The annular ring plate 604 has a central opening, appropriately dimensioned. The annular ring plate 604 may provide flow control by the central opening encouraging flow of dispersed monomer gas towards the centre of the surface of the support 601, and penalising or inhibiting the flow to the edges of the support 601.

In embodiments, a parallel plate 605 may be arranged spaced apart in opposition and substantially parallel to a supporting surface of the support 601 on which the parts to be coated are placed. The parallel plate 605 may provide flow control by serving to inhibit free circulation of the dispersed monomer gases in the chamber in relation to the parts on the support 601.

In other embodiments only a subset of the above described components may be provided in an arrangement of the deposition regulator 600, or other, non-described deposition regulation components may be included configured and arranged to achieve a substantially uniform coating layer on the part or parts.

While the deposition regulator components 600 are shown in FIG. 6B in an “upright” configuration, with parts held on the support 601 by gravity, the deposition regulator components 600 may configured or aligned in another orientation, such as upside down, in which the parts to be coated are temporarily affixed or bonded to the support 601.

The deposition regulation components 600 may be formed of any suitable material such as a plastics material or a metal, and may be coated or otherwise treated to discourage or inhibit condensation, adsorption and adhesion of the monomer gas particles so as to discourage them becoming coated themselves the polymer coating. This may prolong or otherwise continue to allow fine local control of gas flow over repeated coating processes.

As will be seen in the following, by arranging one or more of the deposition regulator components 600 shown assembled in FIG. 6B, the flow of monomer gas can be controlled within the deposition regulator 600 in the deposition chamber to achieve a substantially uniform coating growth rate across parts placed at locations upon the support 601.

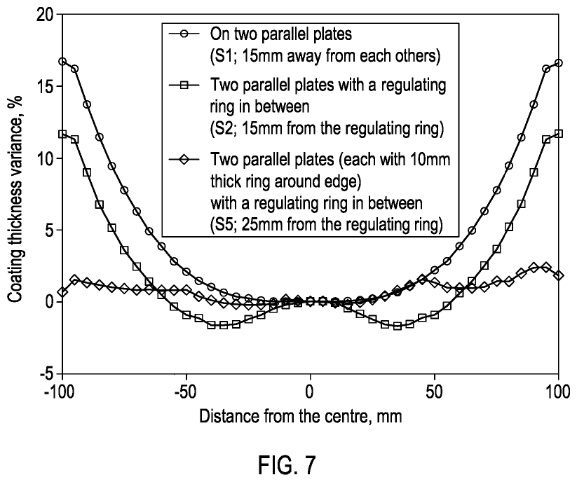

FIG. 7 shows measured coating thickness as deposited using different arrangements of deposition regulator components (S1, S2, S5). The diameter of each support surface 601 in these examples is approximately 200 mm.

In the arrangement of deposition regulator components S1, a support 601 was arranged in a downward configuration with a parallel plate 605 spaced apart in opposition and substantially parallel to a supporting surface of the support 601. As can be seen from the plot of the measurement of the coating thickness deposited on the surface of the support 601 in S1 shown in FIG. 7, this arrangement results in a 17% variation in coating thickness between the edges and the centre of the support 601, with the centre of the support exhibiting the minimum thickness.

In the arrangement of deposition regulator components S2, a support 601 was arranged in an upward configuration with an annular regulation ring 604 spaced apart in opposition and substantially parallel to a supporting surface of the support 601.

In the arrangement of deposition regulator components S3 (not shown in FIG. 7), a support 601 was arranged in a downward configuration also with the annular regulation ring 604 used in S2 spaced apart in opposition and substantially parallel to a supporting surface of the support 601. This arrangement results in a slightly reduced variation of around 13% between the maxima and minima of the coating thickness, with the annular regulation ring controlling the flow of the dispersed monomer particles by the central opening encouraging flow of dispersed monomer gas towards the centre of the surface of the support 601 (hence the central local thickness maxima), and penalising or inhibiting the flow to the edges of the support 601.

In the arrangement of deposition regulator components S4 (not shown in FIG. 7), a support 601 was arranged in an upward configuration with an annular ring baffle 602, having an annular wall, arranged around and extending substantially perpendicular from the supporting surface of the support 601 on which the parts to be coated are placed. Further, a mesh grid 603 was arranged spaced apart in opposition and substantially parallel to a supporting surface of the support 601 at the top of the annular ring baffle 602. Further still, an annular regulation ring 604 was spaced apart in opposition and substantially parallel to a supporting surface of the support 601 at a distance from the mesh (with the mesh between the annular regulation ring 604 and the support 601).

In the arrangement of deposition regulator components S5, a support 601 was arranged like in S4 together with an annular ring baffle 602 and an annular regulation ring 604 spaced apart from the surface of the support 601 but without the mesh grid being provided on the an annular ring baffle 602. As can be seen from the plot of the measurement of the coating thickness deposited on the surface of the support 601 in S5 shown in FIG. 7, this arrangement results in a 1-2% variation in coating thickness between the edges and the centre of the support 601, across a distance of 200 mm.

In this way, the exact size, shape, spacing, combination and configuration of the deposition regulation components 600 can in this way be devised to achieve a substantially uniform growth rate of coating across the surface parts. For example, using the arrangement of deposition regulation components S5, a polymeric conformal coating may be provided across a surface with sufficiently uniform coating thickness, which cannot be achieved without the deposition regulator 600.

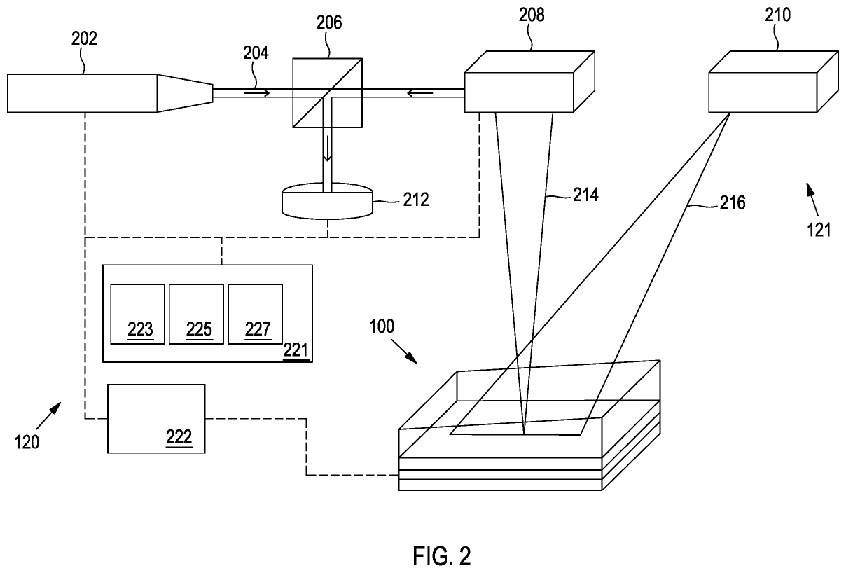

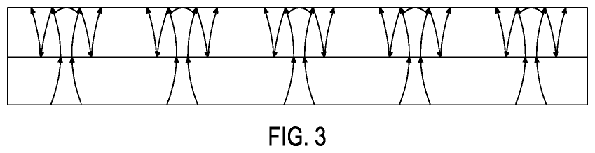

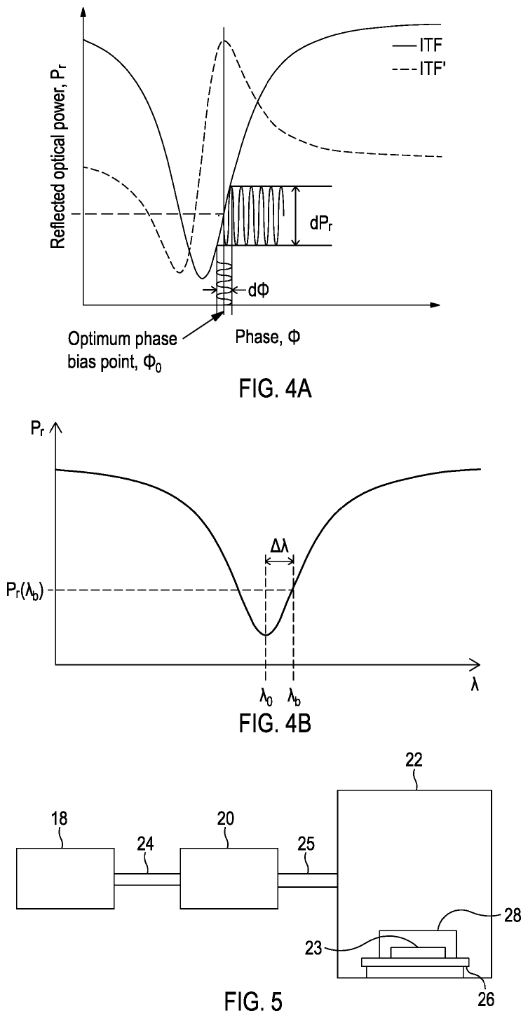

For example, with reference to FIG. 1, the arrangement of deposition regulator components S5 can be used in the production of a polymer film Fabry Perot interferometer 100 having a cavity with highly uniform thickness. FIG. 1 illustrates in more detail a planar Fabry Perot etalon for use in providing a sensor head 100 of an optical ultrasound readout apparatus used in, for example, a photoacoustic tomography apparatus shown in FIG. 2, the operation of which is described below.

The Fabry Perot etalon represents the sensor head 100 or at least the sensing element thereof. The sensor head 100 comprises a wedged transparent polymer backing stub 102 on to which a multilayer sensing structure of the Fabry Perot etalon is vacuum deposited. This includes a spacer 106, typically formed of a Parylene polymer film 10-50 μm thick, depending upon the acoustic bandwidth required, sandwiched between two highly reflective mirrors 104a, 104b typically provided by dichroic dielectric thin film mirrors. The cavity spacer layer 106 may be formed by chemical vapour deposition (CVD) whereas the mirrors 104a, 104b may be formed by sputtering. In the example of the photoacoustic tomography apparatus shown in FIG. 2, the mirrors 104a, 104b, are designed to be highly reflective (i.e. reflects at least 95% of power) in a first wavelength range thus forming with the spacer 104 a high finesse Fabry Perot cavity in this wavelength range but highly transmissive in a second wavelength range. Preferably the first wavelength range is between 1500-1700 nm and the second wavelength range is 600 nm-1200 nm.

By providing the Fabry Perot interferometer 100 having a cavity with highly uniform thickness, the readout of the interferometer for optical ultrasound applications can be performed easily, efficiently and accurately. This is because with a uniformly thick cavity (of say less than 1-2% shape variation across the sensing surface S) there is minimal variation of the cavity thickness that needs to be measured, monitored, accounted and controlled for. Where there is significant variation in cavity thickness, it may be necessary to bias the phase difference between the optical fields reflected by the two mirrors of the cavity during readout to ensure the readout is sensitive, and sensitive to a consistent degree, to the incident acoustic field. With a 10-20% variation in the cavity thickness across the sensing surface, a significant amount of time and error may be incurred in the readout system to measure, monitor, account and control for the phase biasing needed to compensate for this shape variation. This uncontrolled shape variation in the deposited Parylene coating layer can make it difficult to deliver an effective and practical optical ultrasound readout apparatus.

However, by depositing a Parylene conformal coating onto a mirrored Fabry Perot interferometer backing stub 102 as shown in FIG. 1 using the deposition regulator 600 shown in S5 above, a polymeric film interferometer cavity 106 can be formed having less than 1% thickness variation across the surface of the interferometer of 50 mm by 30 mm. This interferometer is a more effective and practical optical ultrasound readout apparatus, because of the consistent response over the surface resulting from the uniform cavity thickness.

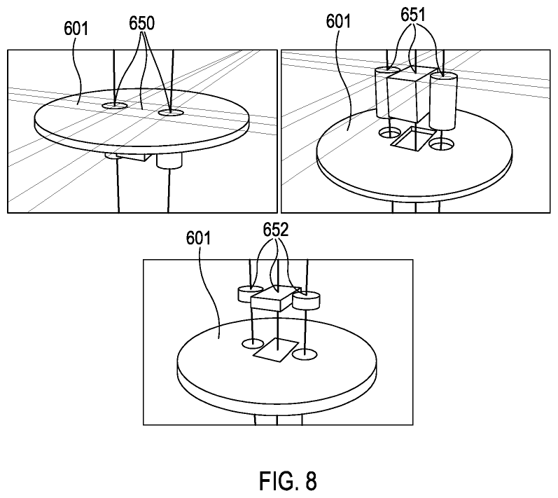

Referring to FIG. 8, where relatively small parts 650 are to be coated (e.g. below 10 mm in diameter), it may be advantageous to embed the small parts 650 in a larger flat surface 601, with the surface of the small parts which is to be coated co-planar with a surface of the larger surface, as illustrated in FIG. 8. This approach removes or reduces topology associated with the smaller parts, and may thereby enhance the uniformity of gas diffusion from which polymer deposition occurs. In an alternative approach, the small parts 652 may be cut from a larger planar part 601, for example, by laser micromachining.

An embodiment of an apparatus for optical ultrasound readout incorporating a planar Fabry Perot polymer coating interferometer formed in accordance with the present disclosure will now be described with reference to FIG. 2, for use in photoacoustic tomography.

In embodiments, apparatus 200 for performing photoacoustic tomography with respect to a sample (not shown) that receives a pulse of excitation electromagnetic radiation and generates an acoustic field in response to said pulse, comprises generally, a sensor head 100, an excitation light source 121 and an interrogation assembly 120.

The excitation light source 121 is arranged to provide through the sensor head 100 an excitation light beam 216 to be absorbed by a tissue sample and to generate a photoacoustic signal field in the tissue to be detected using the sensor head 100 and interrogation assembly 120. The stimulus of the acoustic (ultrasound) field for readout by the sensor head 100 and interrogation assembly 120 can be any suitable stimulus, such as a piezo transducer or a MEMS device, and is not limited to being generated by a pulsed laser using the photoacoustic effect. Further, while the embodiment describes sensing an acoustic field in a tissue sample, this also is not limiting, and the optical ultrasound readout technique, in this embodiment implemented by the sensor head 100 and interrogation assembly 120, may be applied to sense acoustic fields in a range of media and for a range of different applications, such as for non-destructive testing.

In the planar Fabry Perot etalon for use in the sensor head 100, the mirrors 104a, 104b, are designed to be highly reflective (i.e. reflecting at least 95% of power) in a first wavelength range (thus forming with the spacer 104 a high finesse Fabry Perot cavity in this wavelength range) but highly transmissive in a second wavelength range. Preferably the first wavelength range is between 1500-1700 nm and the second wavelength range is 600 nm-1200 nm.

In use, the sensor head 100 is placed such that a sensing surface thereof S is faced against and acoustically coupled to the tissue sample to be imaged (not shown). The sample may include or be covered or coated in a couplant such as a coupling gel, which may be used to ensure the acoustic field is conveyed from the body of the sample (in this case, tissue) to the surface S.

The second wavelength range enables excitation laser pulses from the excitation light source 121 in the near infrared (NIR) window, where biological tissues are relatively transparent, to be transmitted through the sensor head 100 into the tissue. The photoacoustic signals generated by the absorption of the laser energy propagate back to the surface S where they modulate the optical thickness of the spacer 106 and thus the reflectivity of the Fabry Perot sensing structure in the 1500-1700 nm wavelength.

The Fabry Perot etalon of the sensor head 100, having a high finesse, is selectively reflective having a narrowband reflection spectrum, as characterised by the Interferometer Transfer Function (ITF) of locations of the sensor head, which relates the power of the light reflected by the Fabry Perot etalon across different wavelengths in the free spectral range of the cavity, at a given location on the etalon

The central phase point φ₀ or central wavelength λ₀ of the Interferometer Transfer Function at locations across the sensor head is dependent at least in part on the optical path length of light in the cavity, as defined by the thickness of the spacer 106 at those locations. The acoustic signals from the tissue incident on the sensing surface S of the sensor head 100 modulate the optical path length of the cavity of the Fabry Perot etalon at different locations across its surface by acoustic modulation of at least the thickness of the spacer 106. This in turn modulates the central phase point φ₀ and central wavelength λ₀ of the etalon ITF in dependence on the acoustic field incident at that location. Thus, for a single wavelength of light of the ITF, particularly where the ITF slope is high, the reflected power of light of that wavelength is also modulated as the ITF is moved back and forth in wavelength space by the acoustic modulation of the spacer 106. In order to achieve a consistent and desired maximum sensitivity of the reflected power P r to modulation by dPᵣ by the acoustic field, the phase difference between the optical fields in the cavity reflected by the two mirrors of the Fabry Perot Interferometer may be biased accordingly by a bias phase φ_{b}. In embodiments this is selected to be the phase at which the magnitude of dPᵣ is maximised and at which the response is most linear (typically where the value φ where the of the derivative of the ITF is at a maximum). As will be described below The biasing of the phase difference can be achieved by operating the phase biasing means 222 to tune the interrogation light source 202 to a bias wavelength λ_{b} at which the phase difference between the optical fields in the cavity reflected by the two mirrors of the Fabry Perot Interferometer is at the bias phase φ_{b}. As the variation of the thickness of the Parylene cavity 106 is very small (less than 1-2% across the sensing surface S) due to the manufacture method described herein, the bias phase or bias wavelength inherently only needs to be controlled for or changed only very little across the surface during readout.

Referring again to FIG. 2, the interrogation assembly 120 is arranged to optically interrogate the sensor head at locations across the sensor head to reveal the modulation of the reflected power at that location, to enable an image of the photoacoustic field to be reconstructed using tomographic techniques.

In embodiments, the interrogation assembly 120 may comprise a tuneable coherent interrogation light source 202, beam directing means 208, a detection means 212, a controller 221 and a phase biasing means 222. The controller 221 is coupled to the interrogation light source 202, beam directing means 208, detection means 212 and phase biasing means to provide control signals thereto, and to receive detection signals therefrom and is configured to control the interrogation assembly 120 to carry out the methods for performing photoacoustic tomography disclosed in the present application.

The interrogation light source 202 is arranged to provide a focused beam of light 204 to beam directing means 208 which redirects the light to move a scanning beam 214 across the surface the Fabry Perot etalon of the sensor head 100. The interrogation light source 202 is configured to be tuneable by the phase biasing means 222 responsive to control by the controller 221 to tune the wavelength of the light 204 to a bias wavelength λ_{b} at which a bias phase φ_{b} of light in the cavity is obtained. The Fabry Perot etalon of the sensor head 100 is designed and the interrogation light source 202 is selected such that the interrogation light source 102 is tuneable by the phase biasing means 222 across the free spectral range of the Fabry Perot etalon (e.g. a wavelength tuneable laser).

The beam directing means 208 is configured to redirect the focused beam 204 onto the Fabry Perot etalon of the sensor head 100 to point the scanning beam 214 to be incident on the Fabry Perot etalon at any one of a plurality of addressable locations across the plane of the Fabry Perot etalon, which may be specified or represented as values x and y of the x and y axes of a set of planar coordinates on the etalon. The beam directing means 208 is configured to steer the scanning beam 214 to a given addressable location (x,y) based on a control input received from controller 220.

The detection means 212 is arranged to sense the power of the light reflected from the sensor head and to provide a signal indicating the measured reflected power to the controller 221. The interrogation assembly 120 may comprise a beam splitter 206, and/or one or other appropriate optical components which may be arranged to focus the light beam onto the sensor head 100 and to redirect light reflected from the sensor head 100 onto the detection means 212. The detection means 212 may be any component configured to absorb incident light in the tuneable range of the interrogation light source and provide a signal output indicative of the power of the incident light. In embodiments, the detection means 212 may be a photodetector, an active pixel sensor, a charged coupled device, or a bolometer, for example.

The controller 221 may comprise a computer readable medium, which may be a random access memory (RAM) such as one or more volatile or non-volatile memory solid state memory units, such as flash memory. The controller 221 may also comprise one or more data processors.

The computer readable medium of the controller 221 stores scanning wavelength data 223. The scanning wavelength data 223 may be stored as a data array or a look up table or in any other suitable form.

The controller 221 also comprises an interrogation control module 225 and a sensor tuning module 227. The interrogation control module 225 and sensor tuning module 227 may be provided by one or more logical components implemented by one or more data processors of the controller 221 in use.

Alternatively, or in addition, the controller 221 may comprise one or more data processors configured only in use to provide one or more of the said logical components. For example, one or more of the processors may be a general-purpose processor (e.g. a Central Processing Unit) coupled to a memory comprising instructions for configuring the processor to carry out certain steps of the methods described herein. In embodiments, the computer readable medium of the controller 221 that stores the scanning wavelength data 223 may also store instructions which when executed by one or more data processors, cause one or more of the data processors to implement the interrogation control module 225 and carry out the sensor interrogation methods described herein. In embodiments, the computer readable medium of the controller 221 may also store instructions which when executed by one or more data processors, cause one or more of the data processors to implement the sensor tuning module 227 and carry out the sensor tuning methods described herein.

The scanning wavelength data 223 is representative of a set of wavelength values of the wavelength tuneable source 202 for addressable locations (x,y) of the sensor head 100. Specifically, the scanning wavelength data 223 may relate:
addressable locations (x,y) of the sensor head onto which the one or more interrogation beams can be directed in use; and
a respective determined bias wavelength, λ_{b}, for the wavelength source at given addressable locations (x,y), selected to be a tuned wavelength of the source at which the power of the interrogation beam interferometrically reflected from the Fabry Perot cavity is in use modulated by the signal from the acoustic field incident on the acoustically sensitive surface at that location.

The scanning wavelength data 223 can be stored in any appropriate way for controlling the phase difference between the optical fields in the cavity reflected by the two mirrors of the Fabry Perot Interferometer during readout. For example, the data 223 can be stored in a database as tuples each relating a given addressable location (x,y) to the determined bias wavelength λ_{b} for that addressable location, or as a bitmap or as a lookup table (LUT).

The scanning wavelength data 223 is used by the controller 221 to control the beam directing 208 means to direct the interrogation beam to a current addressable location (x,y) of the sensor head and to simultaneously control the phase biasing means 222 to tune the tuneable wavelength interrogation light source 202 to a bias wavelength λ_{b} stored therein to achieve the desired bias phase φ_{b} of light in the optical cavity for the current addressable location (x,y) of the sensor head 100. The controller may perform readout of the addressable locations (x,y) of the sensor head in an appropriate manner, such as by raster scanning. The scanning wavelength data 223 is simultaneously used by the controller 221 to coordinate the received power signal from the detection means 212 with the addressable location being interrogated. As there is little inherent variation in the cavity thickness due to the manufacturing method disclosed herein, only minimal tuning of the phase difference and interrogation source bias wavelength is needed to control for consequent variations in the interferometer sensitivity. This facilitates fast and accurate readout as typically the settling time of the tunable laser following tuning is much longer than the time taken to redirect the interrogation beam using the beam directing means 208.

1. A method of forming a polymeric conformal coating on a surface of a part, comprising:
placing the part and a deposition regulator in a deposition chamber;
dispersing a gas into the chamber and from which the polymeric coating is deposited on the surface;
wherein the deposition regulator is configured to control a localised flow of the gas in the deposition chamber to promote a more uniform layer thickness of the polymeric coating on the surface.

2. The method of claim 1, wherein the deposition regulator comprises an annular ring baffle arranged around and substantially perpendicular to the surface.

3. The method of claim 1 or 2, wherein the gas is dispersed into the chamber from at least one chamber inlets substantially transverse to the surface.

4. The method of any preceding claim, wherein the gas comprises monomer particles and includes a para-xylylene, and wherein the deposited polymer coating is a Parylene.

5. The method of any preceding claim, wherein the surface comprises a first reflector of a part that is, when finished, to provide a Fabry Perot interferometer, wherein the polymeric coating is to provide an optical cavity of the Fabry Perot interferometer.

6. The method of claim 5, further comprising depositing one or more layers on the surface of the deposited polymeric coating to provide a second reflector in opposition to the first reflector, to thereby form the Fabry Perot interferometer.

7. The method of any preceding claim, wherein the arrangement of the deposition regulator is configured to achieve a thickness variation of the polymeric coating across the surface of less than 5%, optionally less than 2%, optionally less than 1%.

8. The method of claim 7, wherein the thickness variation of the deposited coating across the coating surface is achieved over a length scale of at least 10 mm, optionally at least 20 mm, optionally at least 30 mm, optionally at least 50 mm along one dimension of the surface.

9. The method of any preceding claim, wherein the deposition regulator comprises components that include one or more of:
a parallel plate in opposition and substantially parallel to the surface;
an annular ring plate in opposition and substantially parallel to the surface, the annular ring plate having a central opening;
a mesh grid in opposition and substantially parallel to the surface.

10. The method of claim 9, wherein some or all of the components of the deposition regulator comprise a common diameter

11. The method of claim 9 or 10, wherein one or more of a parallel plate, annular ring plate, and mesh grid are spaced at least 4 mm, optionally at least 5 mm, optionally at least 7 mm, optionally at least 10 mm, optionally at least 15 mm, from the surface.

12. The method of claim 9, 10 or 11, wherein the annular ring baffle extends at least 4 mm, optionally at least 5 mm, optionally at least 7 mm, optionally at least 10 mm, optionally at least 15 mm from the surface.

13. The method of any preceding claim, wherein the deposition regulator components comprise a mesh grid arranged proximal to the surface, optionally spaced less than 5 mm therefrom or less than three times the diameter of the mesh hole size.

14. The method of claim 13, wherein the polymeric coating is sandwiched between two reflective surfaces.

15. The of any preceding claim, further comprising evacuating the deposition chamber such that the internal pressure of the chamber is less than 20 Pa.

16. The method of any preceding claim, wherein the deposition chamber is substantially at the ambient temperature.

17. The of any preceding claim, wherein the part is placed on a turntable in the deposition chamber.

18. Apparatus for forming a vapour deposited polymeric conformal coating on a surface of a part to provide a polymeric coating layer, comprising:
a deposition chamber for receiving the part; and
a deposition regulator in the deposition chamber;
one or more chamber inlets configured to disperse a gas into the chamber from which the polymeric coating is deposited on the surface; and
wherein the deposition regulator is configured to control a localised flow of the gas in the deposition chamber to promote a more uniform layer thickness of the polymeric coating on the surface.

19. A coated part having a polymeric conformal coating layer formed by the process of any of claims 1 to 17.

20. The coated part of claim 19, wherein the polymeric coating layer has a thickness variation of less than 5%, optionally less than 2%, optionally less than 1%.

21. The coated part of claim 19 or 20, wherein the thickness variation of the polymeric coating is over a length scale of at least 10 mm, optionally at least 20 mm, optionally at least 30 mm, optionally at least 50 mm along the coating surface.

22. The coated part of claim 19, 20 or 21, wherein the coated part is a Fabry-Perot interferometer, and wherein the polymeric coating provides the interferometric cavity of the Fabry-Perot interferometer.

23. Apparatus for performing acoustic sensing, the apparatus comprising:
a sensor head having a Fabry Perot interferometer comprising the coated part of any of claims 19 to 22, the coated part providing an acoustically sensitive surface arranged as a reflective surface of the Fabry Perot interferometer cavity, and the polymeric coating layer providing the cavity of the Fabry Perot interferometer, wherein an acoustic field incident upon the acoustically sensitive surface modulates the optical path length in the cavity.

24. The apparatus of claim 23, the coated part having reflective surfaces formed on either side of the polymeric coating layer to thereby form the Fabry Perot interferometer.

25. The apparatus of claim 23 or 24, further comprising:
a light source, optionally wavelength tuneable, for generating one or more interrogation beams of light;
controllable beam directing means operable to direct the one or more interrogation beams onto addressable locations (x,y) across said acoustically sensitive surface;
phase control means for controlling the phase difference between the optical fields in the cavity of the Fabry Perot Interferometer, such as by tuning the wavelength of light or by controlling the cavity thickness, to thereby adjust the sensitivity of the apparatus;
detection means configured to receive and determine one or more values representative of the power of the reflected one or more interrogation beams from the addressable locations (x,y); and
a controller configured to, in use, operate one or more of the light source, beam directing means, phase control means, and detection means to:
interrogate addressable locations (x,y) of the sensor head at a phase of light in the cavity at which the reflected light is sensitive to the incident acoustic field; and
receive, from the detection means, values representative of the power of the reflected interrogation beam for each interrogated addressable location of the region; and
form an image indicative of the signal modulated on the reflected one or more interrogation beams by the acoustic field incident on the acoustically sensitive surface at addressable locations (x,y) across the sensitive surface.
